(19) United States
(12) Patent Application Publication
(10) Pub. No.: US 2011/0108847 A1
(43) Pub. Date: May 12, 2011

(54) THIN FILM TRANSISTOR, METHOD OF FABRICATING THE SAME, ORGANIC LIGHT EMITTING DIODE DISPLAY DEVICE HAVING THE SAME, AND METHOD OF FABRICATING THE SAME

(75) Inventor: Yong-Woo PARK, Yongin-city (KR)

(73) Assignee: Samsung Mobile Display Co., Ltd., Yongin-City (KR)

(21) Appl. No.: 12/856,926

(22) Filed: Aug. 16, 2010

(30) Foreign Application Priority Data
Nov. 6, 2009 (KR) 10-2009-0107174

(51) Int. Cl. H01L 33/16; H01L 29/786; H01L 21/336

(52) U.S. Cl. 257/72; 257/66; 438/151; 438/34; 257/E29.292; 257/E21.412; 257/E33.003

(57) ABSTRACT

A thin film transistor (TFT), a method of fabricating the same, an organic light emitting diode (OLED) display device having the same, and a method of fabricating the same. The TFT includes a substrate; a buffer layer disposed on the substrate; a semiconductor layer disposed on the buffer layer; a gate insulating layer disposed on the semiconductor layer; a gate electrode disposed on the gate insulating layer and corresponding to the semiconductor layer; and source and drain electrodes insulated from the gate electrode, and electrically connected to the semiconductor layer. Here, the semiconductor layer includes a plurality of seed regions separated from each other by a distance of 50 μm or more.

### CROSS-REFERENCE TO RELATED APPLICATION

This application claims the benefit of Korean Patent Application No. 10-2009-0107174, filed Nov. 6, 2009, in the Korean Intellectual Property Office, the disclosure of which is incorporated herein by reference.

### BACKGROUND

1. Field

Aspects of the present invention relate to a thin film transistor, a method of fabricating the same, an organic light emitting diode (OLED) display device having the same, and a method of fabricating the same, and more particularly, to a method of forming a semiconductor layer having improved characteristics by easily controlling a metal catalyst inducing crystallization of a silicon layer using a capping layer having a hole, which is formed on a substrate.

2. Description of the Related Art

In general, a polycrystalline silicon layer is widely used for a semiconductor layer for a thin film transistor (TFT) because it is applicable to a circuit having high field effect mobility and high operating speed, and can constitute a CMOS circuit. A thin film transistor using such a polycrystalline silicon layer is mainly used in an active device of an active matrix liquid crystal display (AMLCD) device and switching and driving devices of an organic light emitting diode (OLED) display device.

Methods of crystallizing an amorphous silicon layer into a polycrystalline silicon layer include solid phase crystallization (SPC), excimer laser crystallization (ELC), metal-induced crystallization (MIC), and metal-induced lateral crystallization (MILC). SPC is a method of annealing an amorphous silicon layer for several to several tens of hours at the glass transition temperature of a material used to form a substrate of a display device using a TFT of about 700° C. or lower. ELC is a method of crystallizing an amorphous silicon layer by irradiating the amorphous silicon layer with an excimer laser to heat a local area to a high temperature for a very short time, and MIC is a method of contacting or injecting a metal such as nickel (Ni), palladium (Pd), gold (Au) or aluminum (Al) with or into an amorphous silicon layer for the metal to induce the phase change of the amorphous silicon layer into a polycrystalline silicon layer. MILC is a method of inducing sequential crystallization of an amorphous silicon layer due to continuous lateral propagation of silicide produced by a reaction of metal with silicon.

However, SPC has disadvantages of long processing time and easy deformation of a substrate because the annealing is performed for a long time at a high temperature, ELC has the disadvantage of requiring expensive laser equipment and a poor interface characteristic between a semiconductor layer and a gate insulating layer due to protrusions generated on a polycrystallized surface, and MIC and MILC have disadvantages of an increase in leakage current of a semiconductor layer of a TFT due to a large amount of metal catalysts remaining in a polycrystalline silicon layer.

Presently, the methods of crystallizing an amorphous silicon layer using a metal are being studied because they can crystallize the amorphous silicon layer in a shorter time and at a lower temperature than SPC. The crystallization methods using the metal include MIC, MILC, and super grain silicon (SGS) crystallization. However, in these methods using the metal catalysts, it is difficult to control a seed formed of metal silicide involved with forming a crystal grain, and device characteristics of the TFT can be degraded due to contamination of the semiconductor layer caused by a metal catalyst.

### SUMMARY

Aspects of the present invention provide a thin film transistor having a semiconductor layer whose characteristics are improved because a crystal grain of a polycrystalline silicon layer can be controlled and an amount of metal catalysts present in a semiconductor layer can be reduced by controlling the metal catalysts inducing crystallization using a capping layer having a hole, a method of fabricating the same, an OLED display device having the same, and a method of fabricating the same.

According to an aspect of the present invention, a thin film transistor includes: a substrate; a buffer layer disposed on the substrate; a semiconductor layer disposed on the buffer layer; a gate insulating layer disposed on the semiconductor layer; a gate electrode disposed on the gate insulating layer and corresponding to the semiconductor layer; and source and drain electrodes insulated from the gate electrode, and electrically connected to the semiconductor layer. Here, the semiconductor layer includes a plurality of seed regions, and a distance between the seed regions is 50 μm or more.

According to another aspect of the present invention, an OLED display device includes: a substrate; a buffer layer disposed on the substrate; a semiconductor layer disposed on the buffer layer; a gate insulating layer disposed on the semiconductor layer; a gate electrode disposed on the gate insulating layer and corresponding to the semiconductor layer; source and drain electrodes insulated from the gate electrode and electrically connected to the semiconductor layer; an insulating layer disposed on the substrate; and a first electrode electrically connected to one of the source and drain electrodes, an organic layer and a second electrode. Here, the semiconductor layer includes a plurality of seed regions separated from each other by a distance of 50 μm or more.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIGS. 1A to 1F show a thin film transistor according to an embodiment of the present invention; and

FIG. 2 shows an OLED display device according to another embodiment of the present invention.

### DETAILED DESCRIPTION

The present invention will now be described more fully hereinafter with reference to the accompanying drawings, in which exemplary embodiments of the invention are shown. Like numerals denote the like elements throughout the specification, and when one part is “connected” to another part, these parts may be “directly connected” with each other, or “electrically connected” with each other having a third device therebetween. Moreover, in the drawings, thicknesses of layers and regions are exaggerated for clarity. Reference will now be made in detail to the present embodiments of the present invention, examples of which are illustrated in the accompanying drawings, wherein like reference numerals refer to the like elements throughout. The embodiments are described below in order to explain the present invention by referring to the figures.

Furthermore, it is to be understood that where is stated herein that one layer is “formed on” or “disposed on” another layer, the one layer may be formed or disposed directly on the other layer or there may be intervening layers between the one layer and the other layer. Further, as used herein, the term “formed on” is used with the same meaning as “located on” or “disposed on” and is not meant to be limiting regarding any particular fabrication process. Further, some of the elements that are not essential to the complete understanding of the invention are omitted for clarity.

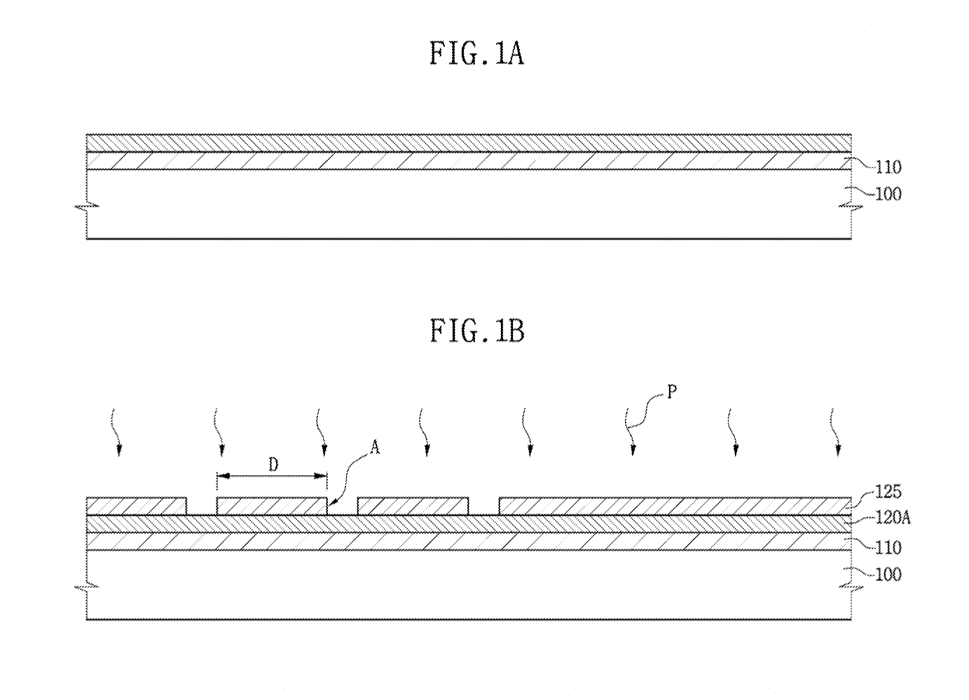

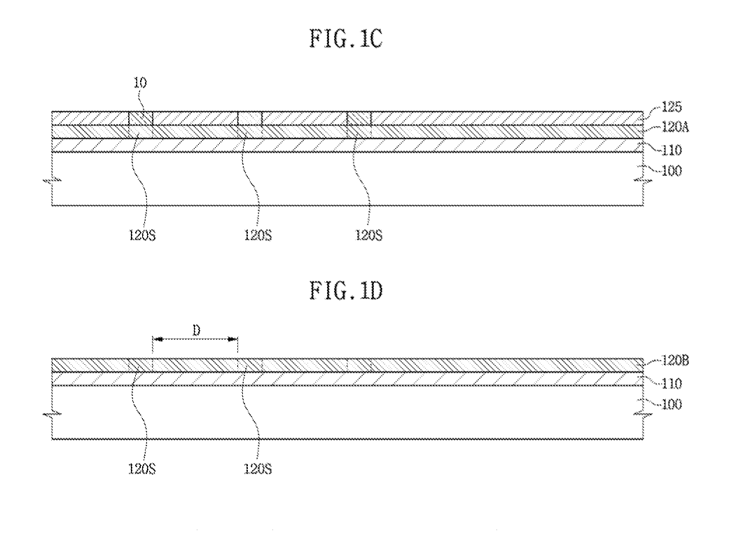

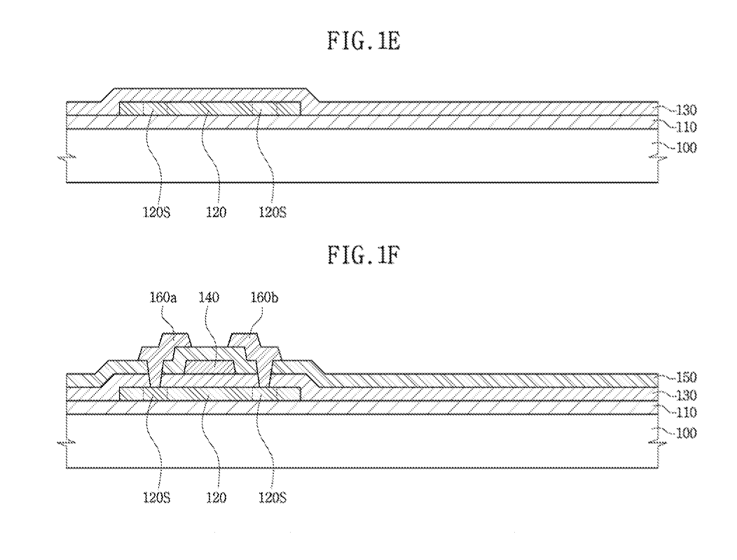

FIGS. 1A to 1F show a thin film transistor (TFT) according to an embodiment of the present invention. First, as shown in FIG. 1A, a buffer layer 110 is formed on a substrate 100 formed of glass or plastic. The buffer layer 110 serves to prevent out-diffusion of moisture or impurities generated from the substrate 100, and is formed by chemical vapor deposition (CVD) or physical vapor deposition (PVD) in a single layer or multilayer structure using insulating layers such as a silicon oxide layer and a silicon nitride layer.

Thereafter, an amorphous silicon layer 120A is formed on the buffer layer 110. The amorphous silicon layer 120A may be formed by CVD or PVD. Moreover, during or after formation of the amorphous silicon layer 120A, a concentration of hydrogen may be reduced by dehydrogenation.

Subsequently, referring to FIG. 1B, a capping layer 125 is formed on the amorphous silicon layer 120A. Here, the capping layer 125 may be formed by CVD or PVD in a single layer or multilayer structure using insulating layers such as a silicon oxide layer and a silicon nitride layer, and have a plurality of holes A exposing a part of the amorphous silicon layer 120A.

A size of the amorphous silicon layer exposed through the hole A is 2 to 10 μm, and a distance between the holes A is 50 μm or more. This is because the size of the diameter of the hole formed by photolithography is at least 2 μm, and when it is more than 10 μm, a large amount of meal catalyst solution fills the hole, so that there is no benefit of forming a small amount of catalysts. In addition, when the distance between the holes A is less than 50 μm, a grain size is relatively smaller, and the amount of the metal catalyst diffused into the amorphous silicon layer is relatively larger. Thus, when the amorphous silicon layer is used for a semiconductor layer after crystallization, characteristics of a TFT can be degraded.

Then, the substrate is treated with plasma to treat a surface of a wall of the hole A with the plasma. The plasma (P) treatment is performed using nitrogen-based or ammonia-based plasma. Afterwards, the substrate is maintained at 30 to 70° C. Due to the plasma treatment and low temperature treatment, a metal catalyst solution can easily penetrate the hole along a partition.

Referring to FIG. 1C, a metal catalyst solution 10 is provided to be in contact with the amorphous silicon layer 120A exposed through the hole A which is treated with the plasma. The metal catalyst solution 10 is provided in the hole A by an inkjet method, and includes a metal catalyst inducing crystallization of the amorphous silicon layer 120A. The metal catalyst includes one selected from the group consisting of Ni, Pd, Ag, Au, Al, Sn, Sb, Cu, Tr and Cd. The metal catalyst solution 10 can prevent the degradation in characteristics of the TFT by controlling an amount of the remaining metal catalysts to have an areal density of 10¹¹ to 10¹⁵ atoms/cm².

Afterwards, the substrate 100 is sintered at a low temperature of 35 to 40° C. to remove a solvent, and annealed at 90 to 110° C. for 5 minutes or more to remove a remaining solvent, so that the metal catalyst can have an innate metallic characteristic.

This is because if the annealing is not performed, the metal catalyst contains a solvent which obstructs the crystallization.

The amorphous silicon layer 120A is crystallized by the metal catalyst solution 10 when the substrate 100 is annealed. Here, the metal catalyst in the metal catalyst solution 10 is diffused to the underlying amorphous silicon layer 120A, thereby forming a seed formed of metal silicide. A crystal is grown from the seed such that the amorphous silicon layer 120A is crystallized into a polycrystalline silicon layer 120B of FIG. 1D.

Referring to FIG. 1D, the seed is formed in a seed region 120S of the amorphous silicon layer 1206 corresponding to a lower portion of the plurality of holes A in the capping layer 125, and a size of the seed region 120S is 2 to 10 μm, which is the same as the hole size. A distance D between the seed regions 120S is 50 μm or more, which is the same as the distance between the holes A in the capping layer 125.

Subsequently, referring to FIG. 1E, the crystallized polycrystalline silicon layer is patterned to form a semiconductor layer 120, and a gate insulating layer 130 is formed on the entire surface of the substrate 100. Here, the semiconductor layer 120 may be patterned to include the seed region 120S, or may be patterned not to include the seed region 120S. The gate insulating layer 130 may be a silicon oxide layer, a silicon nitride layer or a combination thereof.

Referring to FIG. 1F, a gate electrode 140 is formed to correspond to the semiconductor layer 120 on the gate insulating layer 130, and an interlayer insulating layer 150 is formed on the entire surface of the substrate 100. The gate electrode 140 is formed in a single layer structure of aluminum (Al) or an aluminum alloy such as aluminum-neodymium (Al—Nd), or in a multiple layer structure in which an aluminum alloy is stacked on a chromium (Cr) or molybdenum (Mo) alloy.

Afterwards, source and drain electrodes 160a and 160b electrically connected to the semiconductor layer 120 are formed on the interlayer insulating layer 150, and thus a thin film transistor according to the exemplary embodiment of the present invention is completed.

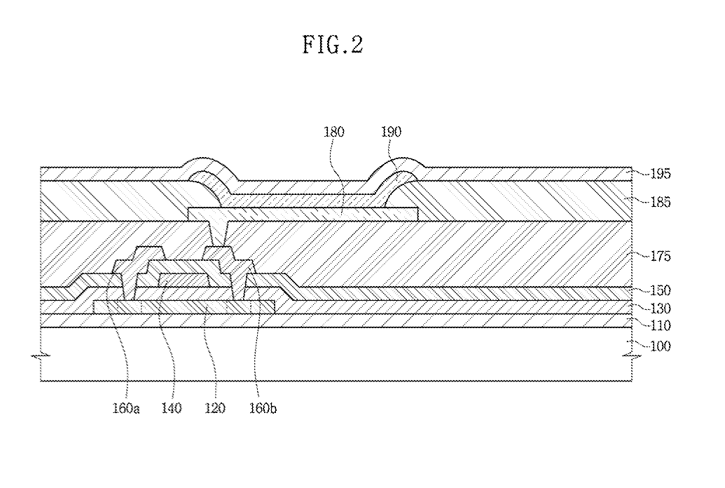

FIG. 2 shows an OLED display device according to an embodiment of the present invention, which has the thin film transistor described in the above embodiment. To avoid repetition, duplicate descriptions will be omitted.

Referring to FIG. 2, an insulating layer 175 is formed on the entire surface of the substrate 100 having the thin film transistor described above. The insulating layer 175 may be an inorganic layer selected from a silicon oxide layer, a silicon nitride layer and a silicate on glass, or an organic layer selected from layers formed of polyimide, benzocyclobutene series resin and acrylate. Alternatively, the insulating layer 175 may be formed in a stacked structure of the inorganic layer and the organic layer.

Then, a first electrode 180 electrically connected to one of the source and drain electrodes 160a and 160b is formed on the insulating layer 175. The first electrode 180 may be formed as an anode or a cathode. When the first electrode 180 is an anode, the anode may be formed using a transparent conductive layer formed of one of ITO, IZO and ITZO, and when the first electrode 180 is a cathode, the cathode may be formed of Mg, Ca, Al, Ag, Ba or an alloy thereof.

Afterwards, a pixel defining layer 185 exposing a part of the first electrode 180 and defining a pixel is formed, and an organic layer 190 including an organic emitting layer is formed on the exposed first electrode 180. The organic layer 190 may further include at least one selected from the group consisting of a hole injection layer, a hole transport layer, a hole blocking layer, an electron blocking layer, an electron injection layer, and an electron transport layer.

Then, a second electrode 195 is formed on the entire surface of the substrate 100, and thus an OLED display device according to an embodiment of the present invention is completed.

A metal catalyst inducing crystallization can be controlled using a capping layer having a hole, thereby controlling a crystal grain of a polycrystalline silicon layer, and reducing an amount of the metal catalyst present in a semiconductor layer. Therefore, an embodiment of the present invention can provide a thin film transistor having the semiconductor layer whose characteristics are improved by a simple method, a method of fabricating the same, an OLED display device having the same, and a method of fabricating the same.

Although an embodiment of the present invention has been described with reference to predetermined exemplary embodiments thereof, it will be understood by those skilled in the art that a variety of modifications and variations may be made to the present invention without departing from the spirit or scope of the present invention defined in the appended claims and their equivalents.

What is claimed is:

1. A thin film transistor (TFT), comprising:
a substrate;
a buffer layer disposed on the substrate;
a semiconductor layer disposed on the buffer layer;
a gate insulating layer disposed on the semiconductor layer;
a gate electrode disposed on the gate insulating layer and corresponding to the semiconductor layer; and
source and drain electrodes insulated from the gate electrode, and electrically connected to the semiconductor layer,
wherein the semiconductor layer includes a plurality of seed regions separated from each other by a distance of 50 μm or more.

2. The TFT according to claim 1, wherein each of the seed regions includes a plurality of metal silicides.

3. The TFT according to claim 1, wherein each of the seed regions has a size of about 2 to 10 μm.

4. The TFT according to claim 1, wherein the semiconductor layer includes one selected from the group consisting of Ni, Pd, Ag, Au, Al, Sn, Sb, Cu, Tr and Cd.

5. A method of fabricating a TFT, comprising:
providing a substrate;
forming a buffer layer on the substrate;
forming an amorphous silicon layer on the buffer layer;
forming a capping layer on the amorphous silicon layer, the capping layer having one or more holes exposing the amorphous silicon layer;
treating the substrate with plasma;
providing a metal catalyst solution to the holes;
annealing the substrate to crystallize the amorphous silicon layer into a polycrystalline silicon layer;
removing the capping layer;
forming a semiconductor layer by crystallizing the polycrystalline silicon layer;
forming a gate insulating layer on the substrate;
forming a gate electrode on the gate insulating layer; and
forming source and drain electrodes insulated from the gate electrode and connected to the semiconductor layer.

6. The method according to claim 5, wherein the plasma treatment is performed using nitrogen-based or ammonia-based plasma.

7. The method according to claim 5, further comprising sintering and annealing the substrate after forming the metal catalyst solution.

8. The method according to claim 7, wherein the sintering is performed at about 30 to 45° C.

9. The method according to claim 7, wherein the annealing is performed at about 90 to 110° C.

10. The method according to claim 5, wherein the metal catalyst solution includes one selected from the group consisting of Ni, Pd, Ag, Au, Al, Sn, Sb, Cu, Tr and Cd.

11. An organic light emitting diode (OLED) display device, comprising:
a substrate;
a buffer layer disposed on the substrate;
a semiconductor layer disposed on the buffer layer;
a gate insulating layer disposed on the semiconductor layer;
a gate electrode disposed on the gate insulating layer and corresponding to the semiconductor layer;
source and drain electrodes insulated from the gate electrode and electrically connected to the semiconductor layer;
an insulating layer disposed on the substrate; and
a first electrode electrically connected to one of the source and drain electrodes, an organic layer and a second electrode,
wherein the semiconductor layer includes a plurality of seed regions, separated from each other by a distance of 50 μm or more.

12. The device according to claim 11, wherein each of the seed regions includes a plurality of metal silicides.

13. The device according to claim 11, wherein each of the seed regions has a size of about 2 to 10 μm.

14. The device according to claim 11, wherein the semiconductor layer includes one selected from the group consisting of Ni, Pd, Ag, Au, Al, Sn, Sb, Cu, Tr and Cd.

15. A method of fabricating an Organic Light Emitting Diode (OLED) display device, comprising:
providing a substrate;
forming a buffer layer on the substrate;
forming an amorphous silicon layer on the buffer layer;
forming a capping layer on the amorphous silicon layer, the capping layer having one or more holes exposing the amorphous silicon layer;
treating the substrate with plasma;
providing a metal catalyst solution to the holes;
annealing the substrate to crystallize the amorphous silicon layer into a polycrystalline silicon layer;
removing the capping layer;
forming a semiconductor layer by crystallizing the polycrystalline silicon layer;
forming a gate insulating layer on the substrate;
forming a gate electrode on the gate insulating layer;
forming source and drain electrodes insulated from the gate electrode and connected to the semiconductor layer;
forming an insulating layer on an entire surface of the substrate; and
forming a first electrode electrically connected to one of the source and drain electrodes, an organic layer and a second electrode.

16. The method according to claim 15, wherein the plasma treatment is performed using nitrogen-based or ammonia-based plasma.

17. The method according to claim 15, further comprising, sintering and annealing the substrate after forming the metal catalyst solution.

18. The method according to claim 17, wherein the sintering is performed at about 30 to 45° C.

19. The method according to claim 17, wherein the annealing is performed at about 90 to 110° C.

20. The method according to claim 15, wherein the metal catalyst solution includes one selected from the group consisting of Ni, Pd, Ag, Au, Al, Sn, Sb, Cu, Tr and Cd.

21. The method according to claim 5, wherein a diameter of each one of the holes, through which the amorphous silicon layer is exposed, is in a range between about 2 to 10 μm.

22. The method according to claim 15, wherein a diameter of each one of the holes, through which the amorphous silicon layer is exposed, is in a range between about 2 to 10 μm.

23. The method according to claim 5, wherein the metal catalyst solution controls an amount of remaining metal catalysts on the one or more holes.

24. The method according to claim 23, wherein an areal density of the remaining metal catalysts is in a range between 10¹¹ to 10¹⁵ atoms/cm².

25. The method according to claim 15, wherein the metal catalyst solution controls an amount of remaining metal catalysts on the one or more holes.

26. The method according to claim 25, wherein an areal density of the remaining metal catalysts is in a range between 10¹¹ to 10¹⁵ atoms/cm².
